(19) United States
(12) Patent Application Publication
(10) Pub. No.: US 2012/0126317 A1
(43) Pub. Date: May 24, 2012

(54) ACCUFET WITH INTEGRATED CLAMPING CIRCUIT

(75) Inventors: Daniel Ng, Campbell, CA (US); Anup Bhalla, Santa Clara, CA (US); Xiaobin Wang, San Jose, CA (US)

(73) Assignee: Alpha and Omega Semiconductor Incorporated, Sunnyvale, CA (US)

(21) Appl. No.: 12/949,218

(22) Filed: Nov. 18, 2010

(51) Int. Cl. H01L 27/06; H01L 21/8234

(52) U.S. Cl. 257/331; 438/237; 257/E27.017; 257/E21.629

(57) ABSTRACT

The present invention features a field effect transistor that includes a semiconductor substrate having gate, source and drain regions; and a p-n junction formed on the semiconductor substrate and in electrical communication with the gate, drain and source regions to establish a desired breakdown voltage. In one embodiment, gate region further includes a plurality of spaced-apart trench gates with the p-n junction being defined by an interface between an epitaxial layer in which the trench gates are formed and the interface with a metallization layer. The breakdown voltage provided is defined, in part by the number of p-n junctions formed. In another embodiment, the p-n junctions are formed by generating a plurality of spaced-apart p-type regions in areas of the epitaxial layer located adjacent to the trench gates.

### BACKGROUND OF THE INVENTION

The present invention generally relates to field effect transistors and more particularly to power accumulation field effect transistors (FETs).

Accumulation mode field-effect transistors, sometimes referred to as “ACCUFETs”, can be formed as trench-type FETs that contain little or no body region like those found in MOSFETs and hence little or no p-n junctions. The region between the trenched gates, referred to as a mesa, and the gate material, typically polysilicon, is doped to provide the ACCUFET with a work function that depletes the mesa region similar to a junction field-effect-transistor (JFET) when the ACCUFET is off. A current path extends between a “source” located at one end (e.g. top) of mesa and a “drain” located at an opposing end (e.g. bottom) of the mesa when a voltage is applied to the gates such that the mesa is not completely depleted. The gate trenches are normally formed in an epitaxial layer that is grown on top of a bottom substrate. Enhancement mode ACCUFETs are off when the gate voltage is equal to the source voltage (i.e., V_{gs}=0). Were V_{gs} increased (in the case of n-type ACCUFETs), the depletion regions surrounding the gates diminish, producing a current path between the source and the drain. Further increasing V_{gs} can form accumulation regions along the trench gate sidewalls, enhancing channel conduction and further lowering the on-resistance of the device.

ACCUFETs may be fabricated with a very high cell density and a very low on-resistance. However, ACCUFETs suffer from drawbacks that hinder the use of the same in power semiconductor devices. Specifically, the lack of clamping structure for limiting the peak drain breakdown voltage makes ACCUFETs susceptible to damage resulting from current/voltage spikes. This is most likely to occur during turn-off of the ACCUFET. Specifically, it has been found that the gate oxide ruptures, causing catastrophic failure of the device. ACCUFETs do not intrinsically have a clamping circuit to clamp the breakdown voltage. A clamping circuit is desired to ensure that the drain voltage does not increase so high as to rupture the fragile gate oxides.

U.S. Pat. No. 5,856,692 discloses an accumulation-mode power MOSFET to overcome the aforementioned deleterious effects. Disclosed is an ACCUFET that has a trenched gate formed in a semiconductor material of a first conductivity type. A region of second conductivity type is formed in the substrate, which may include an epitaxial layer, and a p-n junction diode formed by the region of second conductivity type is connected in parallel with the current path through the accumulation-mode MOSFET. The diode is designed to have a breakdown voltage that causes the diode to break down before the oxide layer surrounding the gate ruptures or is otherwise damaged when the MOSFET undergoes high voltages. However, the diode is formed from a P+ region diffused all the way down to the substrate, which requires a very high thermal budget, which adds to the cost and time for fabricating a device, and may cause other complications. In addition, the P-N junction diode has high reverse recovery charge, Qrr, levels leading to non-ideal switching characteristics, e.g. phase node ringing, induced gate overshoot, etc.

Accordingly, there is a need for a FET device which has the superior cell density and on-resistance characteristics of an ACCUFET yet is able to effectively switch an inductive load or survive voltage spikes of limited energy in a reliable manner particularly without damaging the trench gate.

### SUMMARY OF THE INVENTION

The present invention features a field effect transistor that includes a semiconductor substrate having gate, source and drain regions; and an integrated clamping circuit formed on the semiconductor substrate and in electrical communication with the drain and source regions to establish a desired breakdown voltage. In one embodiment, gate region further includes a plurality of spaced-apart trench gates with the clamping circuit defined by an interface between a semiconductor layer in which the trench gates are formed and a metallization layer. The breakdown voltage provided is defined, in part by the dimensions of the interface formed. In another embodiment, the clamping circuit is formed by generating a plurality of spaced-apart p-type regions in areas of the epitaxial layer located adjacent to the trench gates. These and other embodiments are discussed more fully below.

### BRIEF DESCRIPTION OF THE DRAWINGS

FIG. 1 is a cross sectional partial view of a field effect transistor in accordance with a first embodiment of the present invention;

FIG. 2 is schematic diagram showing the field effect transistor circuit shown in FIG. 1;

FIG. 3 is a top down plan view of the field effect transistor shown in FIG. 1;

FIG. 4 is a top down plan view of the field effect transistor shown in FIG. 3 in accordance with a first alternate embodiment;

FIG. 5 is a cross sectional partial view of a field effect transistor in accordance with a second alternate embodiment of the present invention;

FIG. 6 is a top down plan view of the field effect transistor shown in FIG. 5;

FIG. 7 is a cross sectional partial view of a field effect transistor in accordance with a third alternate embodiment of the present invention;

FIG. 8 is a cross sectional partial view of a field effect transistor in accordance with a fourth alternate embodiment of the present invention; and

FIG. 9 is a top down plan view of the field effect transistor shown in FIG. 8.

### DETAILED DESCRIPTION OF THE INVENTION

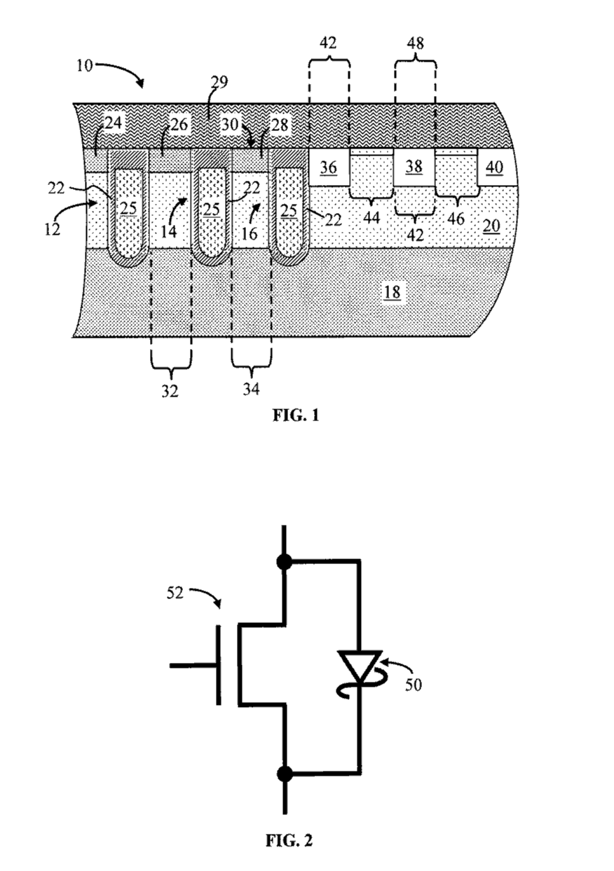

Referring to FIG. 1, an accumulation mode field effect transistor (ACCUFET) integrated circuit 10 includes an ACCUFET defined by a plurality of trench gates 12, 14 and 16 on a semiconductor substrate the semiconductor substrate may include an N+ semiconductor material 18 and an N-type epitaxial layer 20 formed thereon. Trench gates 12, 14 and 16 are formed with polysilicon electrodes insulated from substrate 18 and epitaxial layer 20 with a gate dielectric (e.g., oxide) layer 22. Portions of epitaxial layer 20 positioned adjacent to trench gates 12 and 14 are doped to define N+ regions 24, 26 and 28. N+ regions 24, 26 and 28 are in contact with a conductive layer 29, e.g. metal layer, and function as a source region of the ACCUFET included in integrated circuit 10. Substrate 18 functions as a drain region. Conductive layer 29 is typically formed from a metal, such as aluminum, gold and the like, which defines an interface 30 with the semiconductor surface. Regions 24, 26 and 28 may be doped with a suitable n-type dopant, such as phosphorus, arsenic and the like at implantation energy in a range, for example, of 10 keV to 80 keV, inclusive. Depth of N+ regions 24 and 26 measured from interface 30 can be in a range of 0.1 to 0.25 microns. A distance 32 between adjacent trench gates can be in a range of 0.2 to 0.8 microns and a width 34 of trench gates 12, 14 and 16 may be in a range of 0.1 to 0.5 microns. Gate oxide layer 22 may have a thickness in a range of 50 to 300 angstroms and lines the sides of (e.g. polysilicon) gate material 25 located inside the trench gates.

Formed adjacent to trench gates 12, 14 and 16 are a plurality of spaced-apart regions 36, 38 and 40 doped with a p-type dopant. Regions 36, 38 and 40 are doped with any suitable p-type dopant, such as boron (B) using ion implantation techniques followed with thermal diffusion. By way of example, the implantation energy may be in a range of 10 keV to 60 keV, inclusive. Depth of p-doped regions 36, 38 and 40 measured from interface 30 may be in a range of 0.1 to 1 microns. A width 42 of p-doped regions may be in a range of approximately 0.5 to 2 microns. Regions 44 and 46 between p-doped regions 36, 38 and 40 define a Schottky diode with the epitaxial layer 20 defining the cathode and metallization 29 defining the anode. The Schottky diodes formed at regions 44 and 46 are shielded by the surrounding P-N junctions formed at regions 36, 38, and 40. Regions 44 and 46 function to provide a desired clamping breakdown voltage for the device, which is in part defined by a distance 48 between adjacent between p-doped regions 36, 38 and 40. Distance 48 may be in a range of 0.5 to 2 microns.

Referring to both FIGS. 1 and 2, regions 44 and 46 define a Schottky diode 50 that is coupled in parallel with an ACCUFET 52. The ACCUFET 52 is a vertical discrete device that is integrated with a Schottky diode 50. The ACCUFET 52 may consist of many ACCUFET cells connected in parallel to act as a single discrete ACCUFET device, as indicated by the multiple N+ regions 24, 26 and 28 in contact with metal layer 29 serving as the source, and the bottom substrate 18 serving as the drain. Distance 48, along with the depth and the doping concentration of the P regions, establishes the reverse bias breakdown voltage of Schottky diode 50. Thus, by varying a volume, e.g., distance 48 between and depth of P type regions 36, 38 and 40, as well as and/or doping concentration of the P type regions during fabrication of the integrated circuit 10, a desired breakdown voltage may be provided to the ACCUFET. The breakdown voltage of the Schottky diode 50 clamps the breakdown voltage of the ACCUFET included integrated circuit 10 to a safe level, thus protecting the fragile gate oxide 22, particularly the region of gate oxide 22 located between gate material 25 and the region of epitaxial layer 20 adjacent to gate material 25.

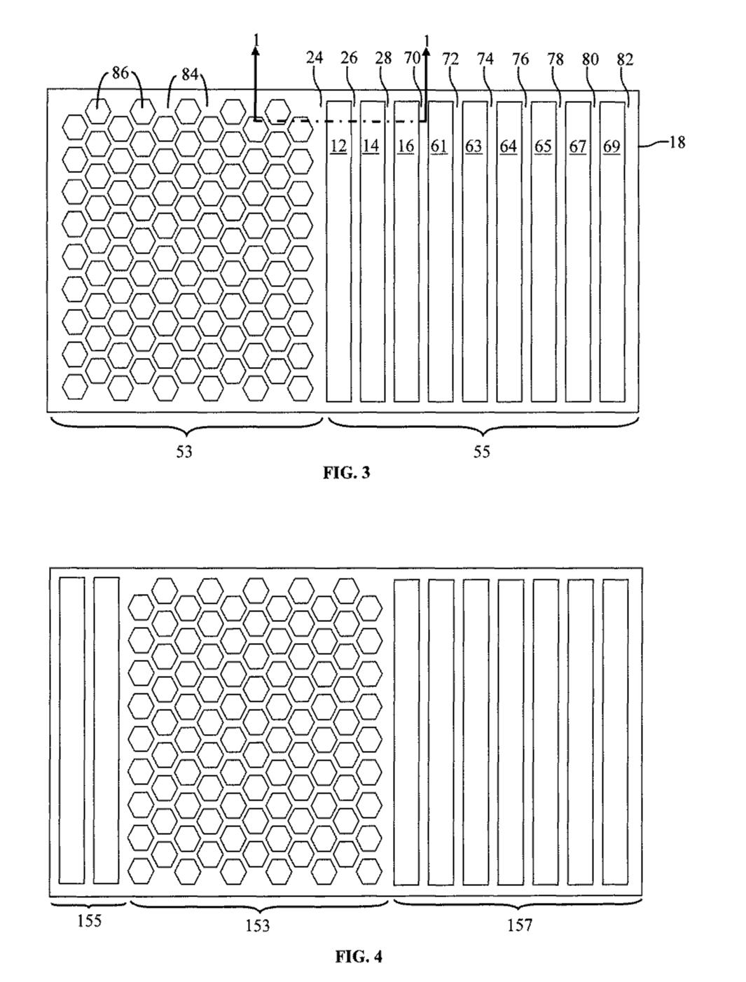

Referring to FIGS. 1, 2 and 3, the layout of the ACCUFET on substrate 18 is configured so that regions 36, 38 and 40 are grouped together. Specifically, on substrate 18, a switching area 55 and a breakdown voltage control area 53 are defined. Switching area 55 corresponds to the ACCUFET 52, and the breakdown voltage control area 53 corresponds to the Schottky diode 50. In switching area 55, trench gates 12, 14, 16, 61, 63, 64, 65, 67 and 69 with N+ regions 24, 26, 28, 70, 72, 74, 76, 78, 80 and 82 being positioned adjacent thereto. Breakdown voltage control area 53 includes a lattice structure 84 comprising p-doped regions such as p-doped regions 36, 38 and 40 of FIG. 1. Lattice structure 84 defines a plurality of spaced-apart polygonal regions 86 in which the n-type epitaxial layer 20 is exposed between the p-type regions of the lattice structure 84. The lattice structure 84 may be analogous to the p-type regions 36, 38, and 40 of FIG. 1 and the polygonal regions 86 may be analogous to the Schottky regions 44 and 46 of FIG. 1. It should be understood, however, that it is not necessary to have all the trench gates 12, 14, 16, 61, 63, 64, 65, 67 and 69 grouped together. For example, a breakdown voltage control area 153 may be flanked by switching areas 155 and 157, as shown in FIG. 4. Also, both closed cell and open cell layouts are possible for both the switching area 55 and the breakdown control area 53.

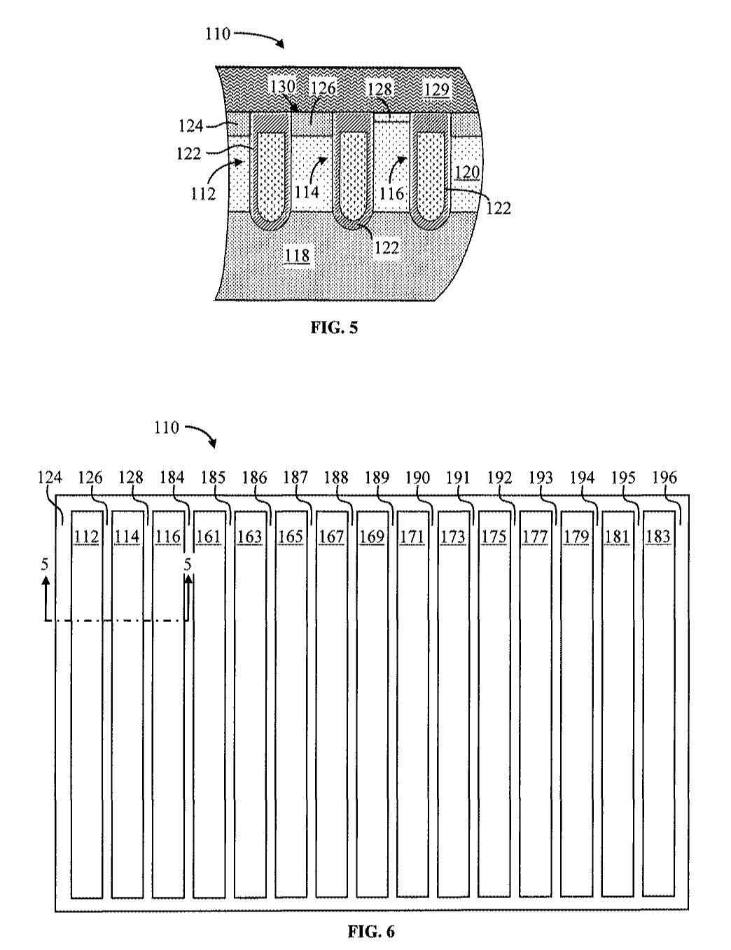

Referring to FIG. 5, in accordance with another embodiment, an ACCUFET integrated circuit 110 includes a plurality of polysilicon trench gates 112, 114 and 116 formed on an N+ semiconductor substrate 118 having an N-type epitaxial layer 120 formed thereon. Trench gates 112, 114 and 116 have the same construction as trench gates 12, 14 and 16 shown in FIG. 1. To that end, the gate electrodes inside each of trench gates 112, 114 and 116, shown in FIG. 5, are each insulated from substrate 118 and epitaxial layer 120 with a gate oxide layer 122. Portions of epitaxial layer 120 positioned adjacent to trench gates 112 and 114 are doped to define N+ regions 124 and 126, while other regions 128 are not doped N+. Regions 124 and 126 function as a source region of the ACCUFET included in integrated circuit 110, with substrate 118 functioning as a drain region. Regions 124, 126 and 128 are in contact with a conductive layer 129 that is typically from a metal, such as aluminum, gold and the like, which defines an interface 130 between conductive layer 129 and the semiconductor surface.

Referring to both FIGS. 2 and 5, regions 124 and 126 may be doped with a suitable n-type dopant, such as Arsenic (As), phosphorous (P), and the like at implantation energy in a range of 1 keV to 5 keV, inclusive. Depth of regions 124 and 126, measured from interface 130, may be in a range of 0.1 to 0.25 microns. Region 128 forms a cathode of Schottky diode 50, with metallization 129 functioning as an anode of the same.

Referring to both FIGS. 5 and 6, the number of regions 128 present in the ACCUFET included in integrated circuit 110 defines in part the breakdown capability of the device. Specifically, the ACCUFET is defined by numerous trench gates 112, 114, 116, 161, 163, 165, 167, 169, 171, 173, 175, 177, 179, 181 and 183. Regions 124, 126, 128, 184-196 may be doped as discussed above with respect to regions 124 and 126 or to region 128. In FIG. 5, n-type dopant is omitted from every three regions 124, 126, 128 and 184-196 providing a ratio of 2:1 n-doped regions (e.g. 124, 126) to non-doped (or lowly doped) regions (e.g. 128). The n+-doped regions (124, 126) form active cells of the ACCUFET, while the undoped regions 128 form cells of the Schottky diode. The trench gates 114, 116 surrounding undoped region 128 help to shield the Schottky diode formed in region 128. However, it should be understood that the ratio may change, dependent upon the application. For example, it may be desired to provide a ratio of the area covered by n+-doped regions to the area covered by non-doped regions as high as 10:1 to optimize circuit performance (although at the cost of clamping capability).

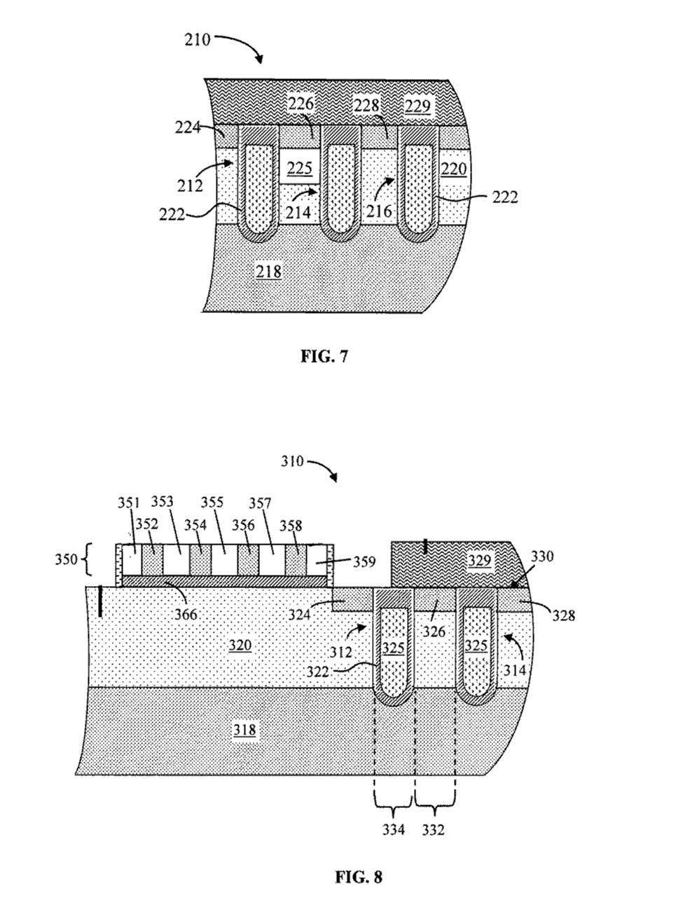

Referring to FIG. 7, another embodiment of the present invention an ACCUFET integrated circuit 210 includes an ACCUFET defined by a plurality of polysilicon trench gates 212, 214 and 216 formed on an N+ semiconductor substrate 218 having n-type epitaxial layer 220 formed thereon. Trench gates 212, 214 and 216 have a construction similar to trench gates 12, 14 and 16 shown in FIG. 1. Each trench gate 212, 214 and 216, is insulated from substrate 218 and epitaxial layer 220 with a gate oxide layer 222. Portions of epitaxial layer 220 positioned between trench gates 212 and 214 are doped with a p-type dopant to form a p-well region 225. At the top thereof is an N+ region 226 that is doped with n-type material. Additionally, regions 224 and 228 are doped with n-type dopants. Regions 224, 226 and 228 are in electrical communication with a metallization layer 229 that may be fabricated as discussed above with respect to metallization layer 29 shown in FIG. 1. Regions 224 and 228 function as a source region of the ACCUFET included in integrated circuit 210. Substrate 218 functions as a drain region of the ACCUFET. A BVceo diode is formed by N+/P/N junctions made by N+ region 226, P base region 225, and N epitaxial layer 220, forming a bipolar transistor, where the P layer is left floating and is not directly contacted by metal. This structure allows tuning of the breakdown voltage by means of adjusting the bipolar gain of the open-based N+/P/N bipolar transistor. Value of the breakdown voltage in this structure is modulated by the bipolar gain of the bipolar transistor. The clamping breakdown voltage can be made lower than that of a simple P-N junction diode. By way of example, increasing the doping concentration of P base region 225 may increase the gain of the bipolar transistor, thus reducing the breakdown voltage of the BVceo diode. In one example, p-type dopant is introduced into epitaxial layer 220 using ion implantation at an energy level in a range of 60-300 keV. By way of example, p-type dopant may be present in P base region 225 at a quantity of 5×10¹² to 3×10¹³ cm⁻² (sheet doping concentration measured per unit area).

Referring to FIG. 8 in yet another embodiment, an ACCUFET integrated circuit 310 includes an ACCUFET defined by a plurality of polysilicon trench gates 312 and 314 formed on an N+ semiconductor substrate 318 having an N-type epitaxial layer 320 formed thereon. Trench gates 312 and 314 are each insulated from substrate 318 and epitaxial layer 320 with a gate oxide layer 322. Top portions of epitaxial layer 320 positioned adjacent to trench gates 312 and 314 are doped to define N+ regions 324, 326, and 328, thus forming a series of back to back Zener diodes. Regions 324, 326 and 328 are in contact with a metallization layer 329 that is typically formed from a metal, such as aluminum, gold and the like, which defines an interface 330 with the semiconductor surface. By way of example, regions 324, 326 and 328 may be doped with a suitable n-type dopant, such as phosphorous, arsenic and the like at implantation energy in a range of 1 keV to 5 keV, inclusive. In this manner, regions 326 and 328 function as a source region of the ACCUFET included in integrated circuit 310. Substrate 318 functions as a drain region of the ACCUFET. Depth of regions 324, 326 and 328 measured from interface 330 may be in a range of 0.1 to 0.25 microns. A distance 332 between trench gates may be in a range of 0.4 to 0.8 microns while a width 334 of trench gates 312 and 314 may be in a range of 0.1 to 0.5 microns. Gate oxide layer 322 may have a thickness in a range of 50 to 300 angstroms and surrounds polysilicon gate material 325, though it may be thicker at the bottom of the trenches.

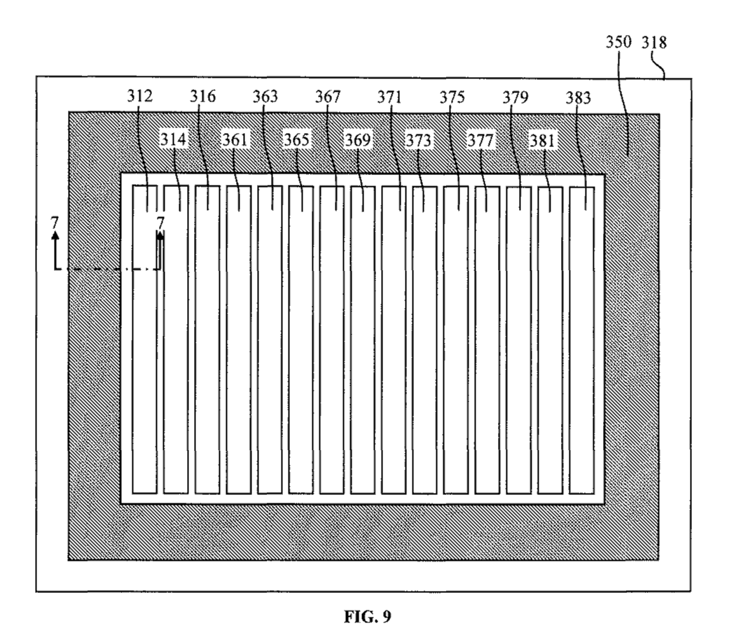

Formed adjacent to metallization layer 329 is a polysilicon (poly) layer 350 having a plurality of p-n junctions formed therein. The p-n junctions are formed from alternating regions of different conductivity type formed into poly layer 350, shown as 351-364. Regions 351, 353, 355, 357, 359, 361 and 363 are doped with p-type dopants. Regions 352, 354, 356, 358, 360, 362 and 364 are doped with n-type dopants. Specifically, a dielectric (e.g., oxide) layer 366 is formed upon a segment of interface 330 not in superimposition with trench gates 312 and 314. Poly layer 350 is formed upon oxide layer 366. The right-most region of poly layer 350 is in electrical communication with metallization layer 329 and, therefore, N+ source regions 326 and 328. The left-most region of poly layer 350, i.e. p-type poly region 351 is in connection with the drain, e.g. through epitaxial layer 320. By way of example, left-most p-type poly region 351 may be connected to the epitaxial layer 320 at the left side of FIG. 7, and thus to the drain through substrate 318. Thus a series of back-to-back P-N Zener diodes is formed along the poly layer 350 between the source and the drain, which clamps the breakdown voltage of the device to a safe level. The breakdown characteristics are determined by the area of poly layer 350, as well as the density of dopants in regions 351-364, as well as the volume of the individual regions, and the number of back to back diodes formed in the poly layer 350. By way of example, poly layer 350 may be disposed to surround trench gates 312, 314, 316, 361, 363, 365, 367, 369, 371, 373, 375, 377, 379, 381 and 383 of the ACCUFET included in the integrated circuit 310, as shown in FIG. 9.

It should be understood that the foregoing description is merely an example of the invention and that modifications and may be made thereto without departing from the spirit and scope of the invention and should not be construed as limiting the scope of the invention. The scope of the invention, therefore, should be determined with respect to the appended claims, including the full scope of equivalents thereof.

1. An integrated circuit comprising:
a semiconductor substrate having formed thereon an accumulation mode field effect transistor (ACCUFET) with gate, source and drain regions; and
a Schottky diode formed on said semiconductor substrate and coupled in parallel with said drain and source regions of said ACCUFET to establish a desired breakdown voltage.

2. The integrated circuit as recited in claim 1 wherein said gate region further includes a plurality of spaced-apart trench gates with a width of said Schottky diode defined by a spacing between adjacent trench gates of a subset of said plurality of trench gates.

3. The integrated circuit as recited in claim 1 further comprising spaced apart p-doped regions wherein said Schottky diode is formed between spaced-apart p-doped regions.

4. The integrated circuit of claim 1 wherein the spaced-apart p-doped regions have a depth in the range of 0.1 to 1 microns, and a distance between adjacent p-doped regions in a range of 0.5 to 2 microns.

5. An integrated circuit comprising:
a semiconductor substrate having formed thereon an accumulation mode field effect transistor (ACCUFET) with gate, source and drain regions; and
a BVceo diode formed on said semiconductor substrate and coupled in parallel with said drain and source regions of said ACCUFET to establish a desired breakdown voltage.

6. The integrated circuit as recited in claim 5 wherein said BVceo diode comprises a bipolar transistor including a first region doped with a first conductivity type at an upper portion of the semiconductor substrate, a second region doped with a second conductivity type below said first region and a portion of said semiconductor substrate under the second region doped with the first conductivity type.

7. The integrated circuit of claim 6 wherein said second region is floating.

8. The integrated circuit of claim 7 wherein the first region doped with a first conductivity type is connected to the source of said ACCUFET, and said portion of said semiconductor substrate under the second region is connected to the drain of said ACCUFET.

9. The integrated circuit of claim 7 wherein said gate region further includes a plurality of spaced-apart trench gates with said first and second regions disposed between adjacent trench gates of a subset of said plurality of trench gates.

10. The integrated circuit of claim 8 wherein the doping of the second region has a sheet doping concentration in the range of 5×10¹² to 3×10¹³ cm⁻².

11. The integrated circuit as recited in claim 5 wherein said gate region further includes a plurality of spaced-apart trench gates with said BVceo diode being defined by a plurality of superimposed doped regions formed by the presence of a first conductivity type in one of said doped regions and second conductivity type in a second of said plurality of doped regions, said second of said plurality of doped regions being located between an overlying region having first conductivity type and an underlying region having first conductivity type.

12. An integrated circuit comprising:
a semiconductor substrate having formed thereon an accumulation mode field effect transistor (ACCUFET) with gate, source and drain regions; and
a series of back to back Zener diodes formed on said semiconductor substrate and coupled in parallel with said drain and source regions to establish a desired breakdown voltage.

13. The integrated circuit as recited in claim 12 wherein said series of back to back Zener diodes is defined by a plurality of p-n junctions.

14. The integrated circuit as recited in claim 12 wherein said series of back to back Zener diodes lie in a plane above a top surface of said semiconductor substrate.

15. The integrated circuit as recited in claim 14 further comprising a polysilicon layer located over a dielectric layer located on a top surface of said semiconductor substrate, wherein said series of back to back Zener diodes are formed in said polysilicon layer.

16. A method of fabricating an accumulation mode field effect transistor (ACCUFET) comprising:
forming on a semiconductor substrate gate, source and drain regions; and
generating on said semiconductor substrate a p-n junction connected in parallel with said source and drain regions, with said p-n junction helping to establish a clamped breakdown voltage.

17. The method as recited in claim 16 wherein forming further includes defining said gate region by creating a plurality of spaced-apart trench gates with said p-n junction being formed between adjacent trench gates of a subset of said plurality of trench gates.

18. The method as recited in claim 17 wherein generating further includes generating a plurality of p-n junctions by forming a first region of first conductivity type at a top portion of said semiconductor substrate between adjacent trench gates, forming a second region of a second conductivity type under the first region, such that a portion of the semiconductor substrate below said second region is first conductivity type.

19. The method as recited in claim 16 wherein generating further includes creating a plurality of spaced-apart p-doped regions with Schottky diodes formed between adjacent spaced-apart p-doped regions.

20. The method as recited in claim 16 wherein generating further comprises configuring said spaced-apart p-doped regions such that they provide shielding for said Schottky diodes.

21. The method as recited in claim 16 wherein generating further includes forming a dielectric layer on a top surface of said semiconductor substrate, forming a layer of semiconductor material over said dielectric layer, and doping said layer of semiconductor material to form a series of alternating first and second regions having first and second conductivity types respectively.
